(19) United States
(12) Patent Application Publication
(10) Pub. No.: US 2002/0153543 A1
(43) Pub. Date: Oct. 24, 2002

(54) METHOD FOR MANUFACTURING OXIDE FERROELECTRIC THIN FILM OXIDE FERROELECTRIC THIN FILM AND OXIDE FERROELECTRIC THIN FILM ELEMENT

(76) Inventor: TAKESHI KIJIMA, URAWA-SHI (JP)

Correspondence Address: Dike, Bronstein, Roberts & Cushman, Intellectual Property Practice Group, EDWARDS & ANGELL, P.O. Box 9169, BOSTON, MA, 02209, US

(21) Appl. No.: 09/407,914

(22) Filed: Sep. 29, 1999

(30) Foreign Application Priority Data
Sep. 29, 1998 (JP) 10(1998-274876

(51) Int. Cl. H01L 31/119; H01L 29/94; H01L 29/76; H01L 27/108

(52) U.S. Cl. 257/296

(57) ABSTRACT

A method of manufacturing an oxide ferroelectric thin film of Bi, Ti and O by an MOCVD method on a substrate having an electrode formed thereon, comprises the step of supplying material gases capable of forming the oxide ferroelectric thin film onto the substrate, wherein an oxygen gas flow rate relative to a total gas flow rate of the material gases is controlled to a value required for obtaining the oxide ferroelectric thin film having a predetermined orientation and/or coercive field, and a flow rate of at least one of the material gases containing constituent elements other than oxygen constituting the oxide ferroelectric thin film is controlled so that a compositional ratio of the constituent elements other than oxygen constituting the oxide ferroelectric thin film is a value required for obtaining the oxide ferroelectric thin film having a predetermined residual polarization and/or relative dielectric constant.

### CROSS-REFERENCES TO RELATED APPLICATIONS

This application is related to Japanese patent application No. HEI 10(1998)-274876 filed on Sep. 29, 1998 whose priority is claimed under 35 USC §119, the disclosure of which is incorporated herein by reference in its entirety.

### BACKGROUND OF THE INVENTION

1. Field of the Invention

The present invention relates to a method for manufacturing an oxide ferroelectric thin film, an oxide ferroelectric thin film and an oxide ferroelectric thin film element. More particularly it relates to a method for manufacturing an oxide ferroelectric thin film, an oxide ferroelectric thin film and an oxide ferroelectric thin film element that can be suitably applied to a memory element, a pyroelectric element, a piezoelectric element, an optical device and the like.

2. Description of the Related Art

Among many oxide materials, some have various properties such as a ferroelectric property, a high dielectric property, a piezoelectric property, a pyroelectric property, an electro-optical effect and the like, and are generally referred to as oxide ferroelectric materials. Development of many devices such as a capacitor, a pressure sensor, an infrared sensor, an oscillator, a frequency filter, an optical switch and the like has been carried out by utilizing these excellent properties of the oxide ferroelectric materials.

Especially, in accordance with recent development of a thin film forming technique, scale reduction of devices and process simplification are attempted by applying a high dielectric property of the oxide ferroelectric materials to a capacitor of a semiconductor device such as a DRAM. Also, development of a device having a novel function such as a non-volatile memory (ferroelectric non-volatile memory) having a high density and operating at a high speed is carried out by applying the ferroelectric property to a memory section of a semiconductor device such as a DRAM.

A ferroelectric non-volatile memory realizes a memory that eliminates the need for a backup power supply by utilizing a ferroelectric property (hysteresis effect) of a ferroelectric substance. For the development of such devices, it is necessary to use a material having a large residual spontaneous polarization and a small coercive field. Further, in order to obtain good electric properties, it is necessary to use a material having a low leakage current and a large durability against repetition of polarization inversion. For this purpose, control of a surface morphology after forming a film is an importance problem. Further, for reduction of an operation voltage and adaptation to fine semiconductor processes, it is desired to realize the above-mentioned properties with a thin film having a thickness of less than several hundred nanometers.

In addition to oxide ferroelectric substances having a perovskite structure shown by the chemical formula ABO₃ which has been studied from the old days, a Bi-based oxide ferroelectric material represented by Bi₂Aₘ₋₁BmO₃ₘ₊₃ is recently attracting people's attention as a material having a strong durability against polarization inversion. Here, A is selected from Li⁺, Na⁺, K⁺, Pb²⁺, Ca²⁺, Sr²⁺, Ba²⁺ and Bi³⁺; B is selected from Fe³⁺, Ti⁴⁺, Nb⁵⁺, Ta⁵⁺, W⁶⁺ and Mo⁶⁺; and m is a natural number of 1 or more.

The crystal structure of an oxide ferroelectric substance represented by Bi₂Aₘ₋₁BmO₃ₘ₊₃ is such that a perovskite layer composed of (m−1) ABO₃ is sandwiched from above and below by (Bi₂O₂)²⁺ layers. A mechanism in which the ferroelectric properties are exhibited is similar to a mechanism in the case of an oxide ferroelectric material represented by ABO₃.

The oxide ferroelectric substances represented by ABO₃ include Pb(Zr_{1-X}Ti_{X})O₃ (hereafter referred to as PZT), BaTiO₃, SrTiO₃, LiNbO₃ and the like, among which PZT has been studied most intensively from the old days.

PZT is a solid solution of PbZrO₃ and PbTiO₃, and has a Zr/Ti ratio of 1 to 1.5. PbTiO₃ is a ferroelectric substance having a perovskite structure that belongs to a tetragonal system and has a spontaneous polarization along a c-axis direction. Although PbZrO₃ is an anti-ferroelectric substance having a perovskite structure that belongs to an orthorhombic system, PbZrO₃ forms a solid solution with PbTiO₃ to increase a Ti content and is transformed into a ferroelectric substance. A thin film using PZT is formed by the sputtering method, the sol-gel method or the like.

The oxide ferroelectric substances represented by Bi₂Aₘ₋₁BmO₃ₘ₊₃ include SrBi₂Ta₂O₉, Bi₄Ti₃O₁₂ and the like. Recently, an eager study on Bi₄Ti₃O₁₂ is carried out.

Bi₄Ti₃O₁₂ belongs to an orthorhombic system and is a ferroelectric substance having a layered perovskite structure as mentioned above. Bi₄Ti₃O₁₂ has two spontaneous polarization components, one along an a-axis direction and the other along a c-axis direction. The spontaneous polarization and the coercive field along the a-axis direction are about 50 it C/cm² and about 50 kV/cm, respectively, while the spontaneous polarization and the coercive field along the c-axis direction are about 4 μC/cm² and about 4 kV/cm, respectively. Therefore, by controlling the orientation of Bi₄Ti₃O₁₂, it is possible to selectively provide the large spontaneous polarization along the a-axis direction or the small coercive field along the c-axis direction in accordance with an intended use of the material.

So far, the sputtering method, the sol-gel method, the laser abrasion method, the MOCVD method and the like have been carried out as a technique for forming a thin film with the above-mentioned ferroelectric materials.

A substrate for forming the above-mentioned oxide ferroelectric material thereon by using one of these film forming methods may be typically a substrate having an electrode made of Pt(111), Ir(111), an electrically conductive oxide material or the like.

It is of great importance to control the orientation and the crystallinity thereof in order to apply the ferroelectric material, which is formed into a thin film by the abovementioned method, to various devices such as a non-volatile memory.

In the case of PZT, although the ferroelectric property of PZT depends largely on the composition x, the film composition is liable to change at the time of forming the film or carrying out a thermal treatment because PZT contains Pb having a high vapor pressure. Therefore, it is difficult to find a factor that determines the orientation or the crystallinity (morphology). As a result, leakage currents and deterioration in durability against polarization inversion are liable to occur in accordance with the reduction of the film thickness due to generation of pinholes, generation of a low dielectric layer caused by reaction of the underlayer electrode Pt and Pb, or the like.

On the other hand, in the case of Bi₄Ti₃O₁₂, it is necessary to perform a thermal treatment of 650° C. or more in order to obtain a good ferroelectric property by means of the conventional sol-gel method, so that the surface directions to be obtained are limited and it is difficult to control the orientation. In the case of forming the film by the MOCVD method, it is reported that, if the film is formed on a Pt electrode at a film forming temperature of 600° C. or more with a Ti bonding layer disposed between the Pt electrode and an SiO₂/Si substrate, the obtained film surface morphology consists of gross crystal particles and also a pyrochlore phase (Bi₂Ti₂O₇) that does not have a ferroelectric property is liable to be generated (See Jan. J. Appl. Phys., 32, 1993, pp. 4086, and J. Ceramic. Soc. Japan, 102, 1994, pp. 512). Therefore, it is difficult to obtain a spontaneous polarization and a coercive field as desired by controlling the orientation and the crystallinity.

Recently, the inventors of the present invention have proposed various methods for controlling the orientation in forming a Bi₄Ti₃O₁₂ ferroelectric thin film by the MOCVD method.

For example, in Japanese Unexamined Patent Publication No. HEI 09(1997)-186376, the orientation of a Bi₄Ti₃O₁₂ ferroelectric thin film is controlled by shifting the Bi/Ti compositional ratio from a stoichiometric composition. However, according to this method, only the magnitude of the (117) component including the a-axis orientation component can be controlled, and it is not possible to obtain control of the c-axis component. Therefore, the coercive field is always as large as 90 kV/cm and it is difficult to apply the obtained thin film to an element operating at a low voltage.

Further, Japanese Unexamined Patent Publication No. HEI 10(1998)-182291 has shown that the dominant orientation can be controlled to a c-axis dominant orientation, a random orientation in which a c-axis component and a (117) component are mixed, or a (117) dominant orientation by changing an oxygen concentration in a material gas. However, since the ferroelectric oxide film is formed on a buffer layer made of TiO₂ in this publication, it is not possible to completely control the c-axis orientation though the dominant orientation may be controlled. Moreover, it is not possible to control the magnitude of each orientation component, so that it is not possible to obtain elements having various saturated-polarization values with the same coercive field, thus providing a limited freedom in the ferroelectric properties.

In addition, the nucleus generation density of the Bi₄Ti₃O₁₂ ferroelectric thin film on a Pt electrode (lower electrode) is usually low, and crystals grow as huge particles. However, since TiO₂ has a good affinity with Pt, it is formed densely on Pt. Therefore, these prior art techniques have failed to provide a ferroelectric thin film having the abovementioned property without a buffer layer.

As described above, if an oxide ferroelectric thin film such as PZT or Bi₄Ti₃O₁₂ is to be formed on a metal electrode such as Pt or Ir by using a film forming technique such as the sol-gel method, the sputtering method or the MOCVD method according to the above-mentioned technique, it is difficult to control the orientation or the crystallinity of the ferroelectric thin film because the ferroelectric thin film must be exposed to a high temperature for a long period of time at the time of forming the film or carrying out a thermal treatment. As a result, it is difficult to suppress the leakage currents generated in the obtained oxide ferroelectric thin film and deterioration in the durability against polarization inversion. Also it is not easy to obtain a spontaneous polarization and a coercive field as desired.

### SUMMARY OF THE INVENTION

The present invention provides a method of manufacturing an oxide ferroelectric thin film of Bi, Ti and O by an MOCVD method on a substrate having an electrode formed thereon, comprising the step of supplying material gases capable of forming the oxide ferroelectric thin film onto the substrate, wherein an oxygen gas flow rate relative to a total gas flow rate of the material gases is controlled to a value required for obtaining the oxide ferroelectric thin film having a predetermined orientation and/or coercive field, and a flow rate of at least one of the material gases containing constituent elements other than oxygen constituting the oxide ferroelectric thin film is controlled so that a compositional ratio of the constituent elements other than oxygen constituting the oxide ferroelectric thin film is a value required for obtaining the oxide ferroelectric thin film having a predetermined residual polarization and/or relative dielectric constant.

Thus, the present invention has been made in order to solve the above-mentioned problems, and the purpose thereof is to obtain a ferroelectric thin film having arbitrary intended ferroelectric properties by completely controlling the orientation (direction and magnitude) including the crystallinity in forming the ferroelectric thin film. Another purpose of the present invention is to suppress the deterioration of the leakage current generated in the oxide ferroelectric thin film and the deterioration of the durability against polarization inversion and to facilitate obtaining a spontaneous polarization and a coercive field as desired, by clearly defining the controlling conditions.

### BRIEF DESCRIPTION OF THE DRAWINGS

The present invention will be better understood from the following detailed description of preferred embodiments of the invention, taken in conjunction with the accompanying drawings, in which:

FIG. 1 is a schematic cross-sectional view showing a structure of a substrate having a Bi₄Ti₃O₁₂ thin film formed thereon as an oxide ferroelectric thin film of the present invention;

FIG. 2 is a view showing a relationship between a Bi flow rate and a Bi/Ti compositional ratio for each oxygen concentration in the Bi₄Ti₃O₁₂ thin film fabricated in accordance with Example 1 of the present invention;

FIGS. 3(a) to 3(b) are views showing a correlation between an oxygen concentration and a Bi/Ti compositional ratio of the XRD pattern of the Bi₄Ti₃O₁₂ thin film fabricated in accordance with Example 1 of the present invention;

FIG. 4 is a view showing a correlation between an oxygen concentration and a Bi/Ti compositional ratio of the XRD pattern of the Bi₄Ti₃O₁₂ thin film fabricated in accordance with Example 1 of the present invention;

FIGS. 5(a) to 5(b) are views each showing a correlation of an XRD peak intensity of the Bi₄Ti₃O₁₂ thin film fabricated in accordance with Example 1 of the present invention;

FIG. 6 is a schematic cross-sectional view showing a Bi₄Ti₃O₁₂ ferroelectric thin film capacitor fabricated in accordance with Example 2 of the present invention;

FIGS. 7(a) to 7(c) are views each showing a hysteresis property when an alternating current voltage having the maximum voltage of 5V is applied to the Bi₄Ti₃O₁₂ ferroelectric thin film capacitor fabricated in accordance with Example 2 of the present invention;

FIGS. 8(a) to 8(c) are views showing saturation properties of a residual spontaneous polarization Pr of the Bi₄Ti₃O₁₂ ferroelectric thin film capacitor fabricated in accordance with Example 2 of the present invention;

FIGS. 9(a) to 9(c) are views showing saturation properties of a coercive field Ec in the Bi₄Ti₃O₁₂ ferroelectric thin film capacitor fabricated in accordance with Example 2 of the present invention;

FIG. 10(a) is a view showing a relationship between the Bi/Ti compositional ratio and the residual spontaneous polarization Pr when an alternating current voltage having the maximum voltage of 5V is applied to the Bi₄Ti₃O₁₂ ferroelectric thin film capacitor fabricated in accordance with Example 2 of the present invention;

FIG. 10(b) is a view showing a relationship between the Bi/Ti compositional ratio and the coercive field Ec when an alternating current voltage having the maximum voltage of 5V is applied to the Bi₄Ti₃O₁₂ ferroelectric thin film capacitor fabricated in accordance with Example 2 of the present invention;

FIG. 11(a) to 11(c) are views each showing a hysteresis property of a Bi₄Ti₃O₁₂ ferroelectric thin film capacitor having a stoichiometric composition (Bi/Ti=1.33) formed in accordance with Example 2 of the present invention;

FIG. 12 is a view showing a hysteresis property when an alternating current voltage having the maximum voltage of 5V is applied to a Bi₄Ti₃O₁₂ ferroelectric thin film capacitor having a stoichiometric composition (Bi/Ti=1.33) formed in accordance with Example 2 of the present invention;

FIG. 13 is an SEM image of the Bi₄Ti₃O₁₂ ferroelectric thin film having a stoichiometric composition (Bi/Ti=1.33) formed in accordance with Example 2 of the present invention;

FIG. 14(a) is a schematic cross-sectional explanatory view showing a Bi₄Ti₃O₁₂ ferroelectric thin film in a state having a structure which includes an amorphous layer and a BIT layer connected in series;

FIG. 14(b) is a view showing a hysteresis property of the Bi₄Ti₃O₁₂ ferroelectric thin film having a structure which includes an amorphous layer and a BIT layer connected in series;

FIG. 15 is an explanatory view showing a pillar-shaped structure of the Bi₄Ti₃O₁₂ ferroelectric thin film of the present invention;

FIG. 16 is a view showing a relative dielectric constant of the Bi₄Ti₃O₁₂ ferroelectric thin film formed in accordance with Example 2 of the present invention;

FIGS. 17(a) to 17(c) are views each showing a fatigue property of the Bi₄Ti₃O₁₂ ferroelectric thin film capacitor fabricated in accordance with Example 2 of the present invention.

### DETAILED DESCRIPTION OF THE PREFERRED EMBODIMENTS

A substrate that can be used in the method of manufacturing an oxide ferroelectric thin film according to the present invention may be, for example, a semiconductor substrate such as an element semiconductor of silicon, germanium or the like or a compound semiconductor of GaAs, ZnSe or the like; a metal substrate of Pt or the like; or a dielectric substrate such as a sapphire substrate, an MgO substrate, a SrTiO₃ substrate, a BaTiO₃ substrate or a glass substrate. Among these, a silicon substrate is preferable, and especially a silicon single crystal substrate is preferable.

An electrode is formed on the substrate. The electrode may be formed of any material as long as it is an electrically conductive material. For example, the electrode may be formed of a metal such as Pt, Ir, Au, Al, Ru or the like, or an electrically conductive oxide such as IrO₂ or RuO₂. The electrode may be formed, for example, by the sputtering method, the vapor deposition method, the EB method or the like. The thickness of the electrode may be, for example, 100 nm to 200 nm.

Intermediate layers such as a dielectric layer and/or a bonding layer may be formed between the electrode and the substrate. The dielectric layer may be formed, for example, of SiO₂ or SiN. The bonding layer may be made of any material as long as it can ensure a bonding strength between the substrate and the electrode or between the dielectric layer and the electrode. For example, the bonding layer may be made of a high melting point metal such as tantalum or titanium. These intermediate layers may be made by a variety of methods such as the thermal oxidation method, the CVD method, the sputtering method, the vacuum vapor deposition method, or the MOCVD method.

First, in the manufacturing method of the present invention, a substrate such as mentioned above is placed in a film forming chamber for forming oxide ferroelectric thin films. The film forming chamber to be used in the present invention may be any film forming chamber as long as the pressure in the chamber can be controlled, and material gases, oxygen gas, and carrier gas can be supplied. Among these, the film forming chamber is preferably a film forming chamber of a film forming apparatus capable of forming a film by the MOCVD method.

Next, two or more kinds of material gases containing elements other than oxygen constituting the oxide ferroelectric substance are supplied onto the substrate together with the oxygen gas. During this step, a carrier gas or a balance gas such as argon or helium may be supplied together with these gases.

The oxygen gas is preferably a 100% pure oxygen gas, although it may be a diluted one. In introducing the oxygen gas into the film forming chamber, it is necessary that the oxygen gas flow rate relative to the total flow rate of the material gases is controlled to a value required in obtaining the oxide ferroelectric thin film having a predetermined orientation and/or a coercive field. For example, the oxygen gas flow rate may be within the range of about 33 to about 80 vol %. The term “predetermined orientation” as used herein represents an orientation (direction, magnitude) including the crystallinity, such as a c-axis dominant orientation, a random orientation in which a c-axis orientation and a (117) orientation are mainly dominant, or a (117) dominant orientation.

Also, it is necessary that the flow rate of at least one of the material gases containing the constituent elements other than oxygen constituting the oxide ferroelectric thin film is controlled so that a compositional ratio of constituent elements other than oxygen constituting the oxide ferroelectric thin film is a value required in obtaining the oxide ferroelectric thin film having a predetermined residual polarization and/or a relative dielectric constant. For example, in order to obtain such a predetermined residual polarization, the flow rate of at least one of the material gases containing Bi or Ti is controlled so that the Bi/Ti compositional ratio of the oxide ferroelectric thin film is within the range of 0.4 to 1.5. The term “predetermined residual spontaneous polarization” as used herein represents a high residual polarization value Pr and/or a good angular (parallelogram) shape of the hysteresis curve.

Further, it is possible to control a density of crystal nucleation in the oxide ferroelectric thin film by controlling a Bi/Ti compositional ratio by varying a flow rate of at least one of material gases containing constitutional elements other than oxygen constituting the oxide ferroelectric thin film.

The oxide ferroelectric thin film to be obtained in accordance with the present invention is not limited as long as it is made of an oxide ferroelectric material represented by Bi₂Xₘ₋₁YₘO₃ₘ₊₃ where X is an element selected from the group consisting of Li⁺, Na⁺, K⁺, Pb²⁺, Ca²⁺, Sr²⁺, Ba²⁺ and Bi³⁺; Y is an element selected from the group consisting of Fe³⁺, Ti⁴⁺, Nb⁵⁺, Ta⁵⁺, W⁶⁺ and Mo⁶⁺; and m is a natural number of 1 or more. Further, it may be an oxide ferroelectric thin film represented by Bi₂Aₘ₋₁BmO₃ₘ₊₃ such as SrBi₂Ta₂O₉ having the same crystal structure, which is the source of the ferroelectric properties. Also, since the oxide ferroelectric thin film material represented by Bi₂Aₘ₋₁BₘO₃ₘ₊₃ contains an ABO₃ structure in its crystal structure and the source of the ferroelectric properties lies in the ABO₃ structure portion, the ferroelectric thin film may be made of an oxide ferroelectric material represented by ABO₃ such as PZT, BaTiO₃ or SrTiO₃. Among these, the oxide ferroelectric thin film may be Bi₄Ti₃O₁₂, and more preferably has a layered perovskite crystal structure.

The oxide ferroelectric thin film element according to the present invention is not limited as long as it is an element including the oxide ferroelectric thin film of the present invention as a dielectric film. For example, the oxide ferroelectric thin film element may have a structure in which the oxide ferroelectric thin film is sandwiched between a pair of electrodes.

Hereafter, embodiments of the method for manufacturing the oxide ferroelectric thin film, the oxide ferroelectric thin film, and the oxide ferroelectric thin film element according to the present invention will be described with reference to the attached drawings.

### EXAMPLE 1

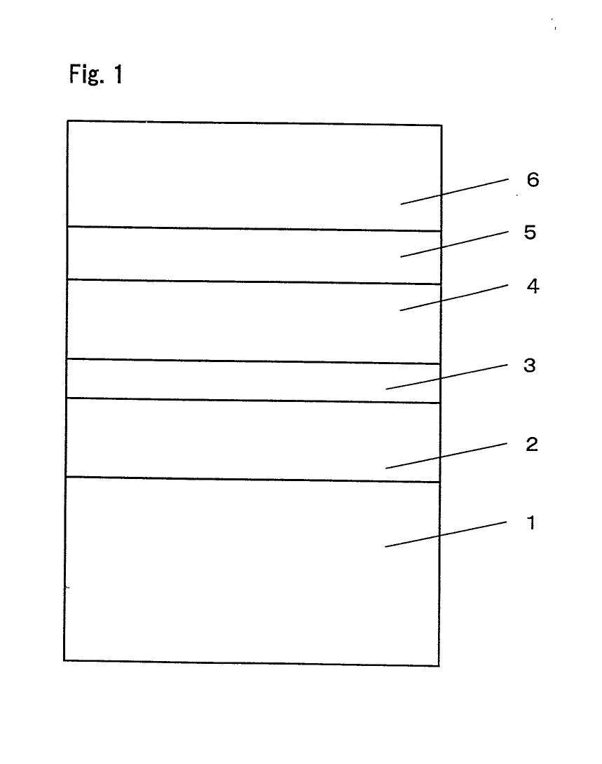

FIG. 1 is a view showing a substrate having a ferroelectric thin film formed thereon according to this embodiment of the present invention. This substrate having a ferroelectric thin film formed thereon includes a silicon oxide (SiO₂) layer 2, a tantalum layer 3 as a bonding layer, a Pt lower electrode 4, a Bi₄Ti₃O₁₂ ferroelectric initial nucleus layer 5 (hereafter referred to as Bi₄Ti₃O₁₂ initial nucleus layer 5), and a Bi₄Ti₃O₁₂ ferroelectric growth layer 6 (hereafter referred to as Bi₄Ti₃O₁₂ growth layer 6) which are laminated in this order on a silicon single crystal substrate 1.

The substrate having the ferroelectric thin film formed thereon was fabricated as follows.

First, a silicon oxide layer 2 was formed to a thickness of about 200 nm on a silicon single crystal substrate 1 by thermal oxidation of a surface of the substrate. A tantalum layer 3 and a Pt lower electrode layer 4 were successively formed to a thickness of about 30 nm and a thickness of about 200 nm, respectively, on the silicon oxide layer 2 by the sputtering method.

Then, a Bi₄Ti₃O₁₂ growth layer 6/Bi₄Ti₃O₁₂ initial nucleus layer 5 were formed by the MOCVD method.

The common film forming condition at this step is as follows. An Ar carrier gas containing a Ti material, an oxygen gas as a reaction gas, an Ar gas as a balance gas were introduced into a film-forming chamber and further, at the time of forming the Bi₄Ti₃O₁₂ growth layer 6/Bi₄Ti₃O₁₂ initial nucleus layer 5, an Ar carrier gas containing a Bi material was introduced into the film-forming chamber. The pressure in the film-forming chamber was set to 5 Torr, and the flow rate of the Ar carrier gas containing the Ti material was fixed at 50 sccm. The flow rate of the total gases (Ar carrier gases containing the Bi material and the Ti material, the oxygen gas and the Ar balance gas) introduced into the film-forming chamber was fixed at 2500 sccm.

The Bi₄Ti₃O₁₂ initial nucleus layer 5 was formed to a thickness of 5 nm on the Pt lower electrode 4 at a substrate temperature of 550° C. Then, the substrate temperature was set to 400° C., and the Bi₄Ti₃O₁₂ growth layer 6 was successively grown to a thickness of 190 nm to obtain a total film thickness of 200 nm. The film forming conditions for forming the Bi₄Ti₃O₁₂ initial nucleus layer 5 and the Bi₄Ti₃O₁₂ growth layer 6 are shown in Table 1.

TABLE 1

| Precursor | Bi(o-C₂H₇)₃ | Ti(i-OC₃H₇)₄ |
|---|---|---|
| Precursor temperature | 160° C. | 50° C. |
| Gas flow rate | 50-350 sccm | 50 sccm |

| | |
|---|---|
| Ar carrier gas | 825 sccm (33%) |
| O_{2 gas} | 1250 sccm (50%) |
| | 2000 sccm (80%) |
| Total gas flow rate | 2500 sccm |
| Pressure | 5 Torr |
| Substrate | Pt/Ta/SiO₂/Si(100) |
| Substrate temperature | 550° C. (initial nucleus layer) |
| | 450° C. (growth layer) |

In forming the Bi₄Ti₃O₁₂ initial nucleus layer 5 and the Bi₄Ti₃O₁₂ growth layer 6, several kinds of Bi₄Ti₃O₁₂ growth layer 6/Bi₄Ti₃O₁₂ initial nucleus layer 5 were formed by supplying the flow rate of the Ar carrier gas containing the Ti material with 50 sccm, varying the flow rate of the Ar carrier gas containing the Bi material within the range of 50 to 350 sccm and varying the oxygen gas flow rate within the range of 825 to 2000 sccm (oxygen concentration: 33 to 80% relative to the total gas flow rate). When the flow rate of the Ar carrier gas containing the Bi material and the oxygen flow rate were set before forming the Bi₄Ti₃O₁₂ initial nucleus layer 5, the subsequent Bi₄Ti₃O₁₂ growth layer 6 was formed under the same film-forming condition.

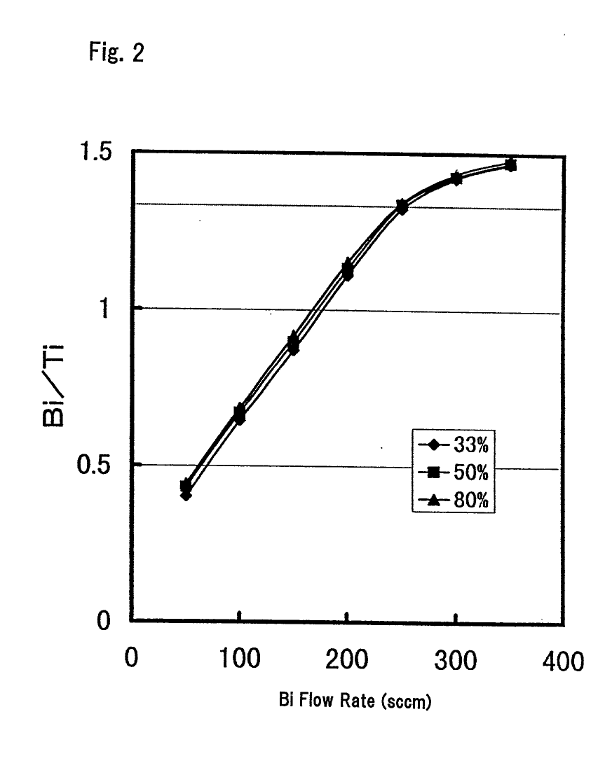

The Bi content (Bi/Ti compositional ratio) of each of the Bi₄Ti₃O₁₂ growth layers 6 obtained as above was measured by EPMA. The results are shown in FIG. 2, which shows a relationship between the flow rate of the Ar carrier gas containing the Bi material and the Bi/Ti compositional ratio using the oxygen gas concentration (oxygen gas flow rate/total gas flow rate; 2500 sccm) as a parameter.

From FIG. 2, it will be understood that, irrespective of the oxygen gas concentration, the Bi/Ti compositional ratio changes within the range of 1.5 or less, and the Bi/Ti compositional ratio increases in proportion to the flow rate of the Ar carrier gas containing the Bi material in the range of less than or equal to the stoichiometric composition of Bi/Ti=1.33, whereas the Bi/Ti compositional ratio tends to be saturated around 1.5 when the Bi/Ti compositional ratio exceeds the stoichiometric composition.

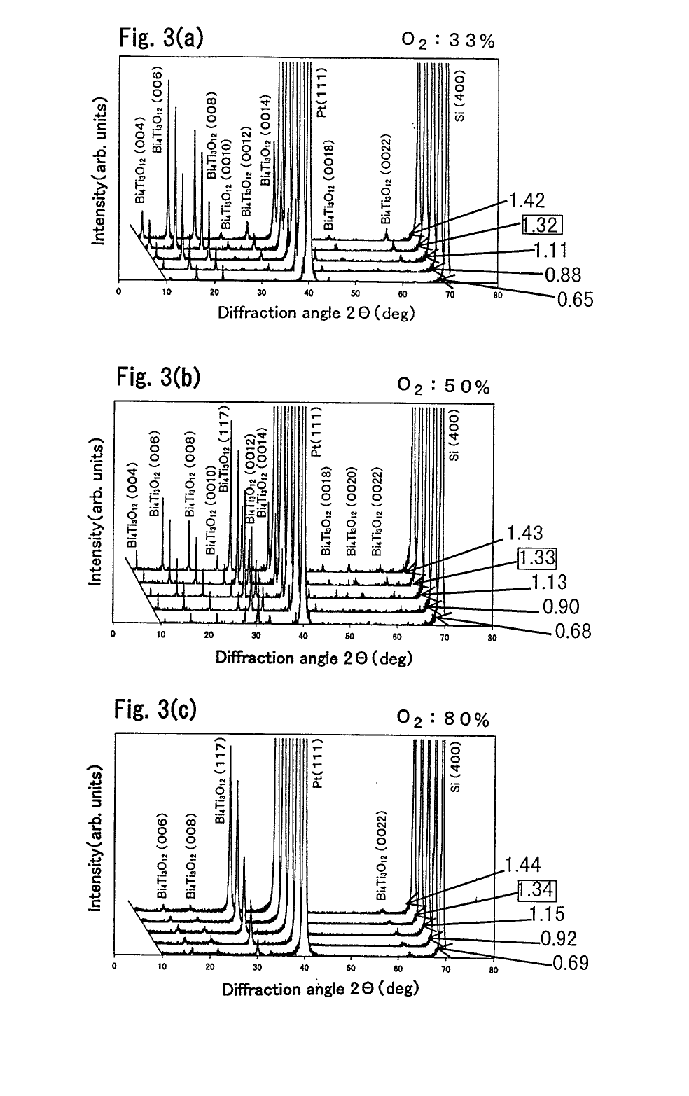

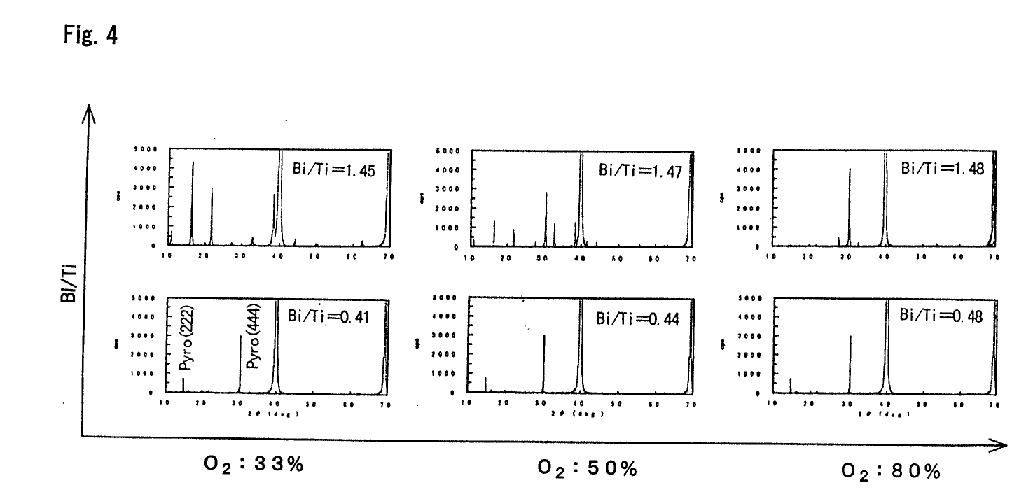

Also, XRD (X-ray diffraction) patterns of various Bi₄Ti₃O₁₂ growth layers fabricated in the Example 1 were measured. The results are shown in FIGS. 3(a) to 3(b) and 4. In FIGS. 3(a) to 3(b) and 4, the horizontal axis represents the oxygen gas concentration, and the vertical axis represents the Bi content (Bi/Ti compositional ratio). The patterns are all shown together in one graph.

As will be understood from FIGS. 3(a) to 3(b) and 4, all the Bi₄Ti₃O₁₂ growth layers showed a layered perovskite (ferroelectric) phase at Bi/Ti≧0.65 if the oxygen concentration was 33% or more.

Further, if the oxygen concentration was 33%, the Bi₄Ti₃O₁₂ growth layer showed almost a single c-axis orientation. According as the oxygen gas concentration is increased, the c-axis component gradually decreases, and instead a (117) component containing an a-axis component appears. Thus, in accordance with the increase in the oxygen gas concentration, the Bi₄Ti₃O₁₂ growth layer showed a random orientation in which the c-axis component and the (117) component are mixed. For example, if the oxygen concentration is 50%, the XRD peak intensity ratio is (008): (117)≈1:4. When the oxygen concentration was further increased to 80%, the Bi₄Ti₃O₁₂ growth layer showed almost a single (117) orientation.

Next, an explanation will be given on XRD patterns in the case where the Bi/Ti compositional ratio of the vertical axis is changed.

In the case where the oxygen gas concentration was 33%, namely in the case where the Bi₄Ti₃O₁₂ thin film almost completely showed a c-axis orientation, and if the Bi/Ti compositional ratio was less than or equal to the stoichiometric composition (Bi/Ti=1.33), the XRD peak intensities (especially (006) and (008)) of the c-axis orientation components increased in proportion to the increase in the Bi/Ti compositional ratio. Further, the XRD peak intensities of the c-axis orientation components increase also when the Bi/Ti compositional ratio exceeded the stoichiometric composition (Bi/Ti=1.33). However, the XRD peak intensities of the c-axis orientation components showed a tendency of saturation at around Bi/Ti=1.5.

In the case where the oxygen gas concentration was 50%, the Bi₄Ti₃O₁₂ thin film showed a random orientation and, in accordance with the increase in the Bi/Ti compositional ratio, the XRD peak intensities of both the c-axis orientation components and the (117) orientation component increase in the same manner as in the case where the oxygen gas concentration is 33%, with the XRD peak intensity ratio of the (008) orientation component of the c-axis orientation components to the (117) orientation component maintained at about 1:4. When the Bi/Ti compositional ratio comes near to 1.5, the peak intensities of both the c-axis orientation components and the (117) orientation component showed a tendency of saturation with the XRD peak intensity ratio of the (008) orientation component of the c-axis orientation components to the (117) orientation component maintained at about 1:4.

In the case where the oxygen gas concentration was 80%, namely in the case where the Bi₄Ti₃O₁₂ thin film showed almost a single (117) orientation, the (117) peak intensity increased in the XRD pattern in accordance with the increase in the Bi/Ti compositional ratio, and the (117) peak intensity showed a tendency of saturation at around Bi/Ti=1.5. Here, as shown in FIG. 4, the Bi₄Ti₃O₁₂ thin films formed with Bi/Ti≈0.4 (Bi flow rate: 50 sccm) all showed a paraelectric (ordinary dielectric) pyrochlore (Bi₂Ti₂O₇) phase irrespective of the orientation direction.

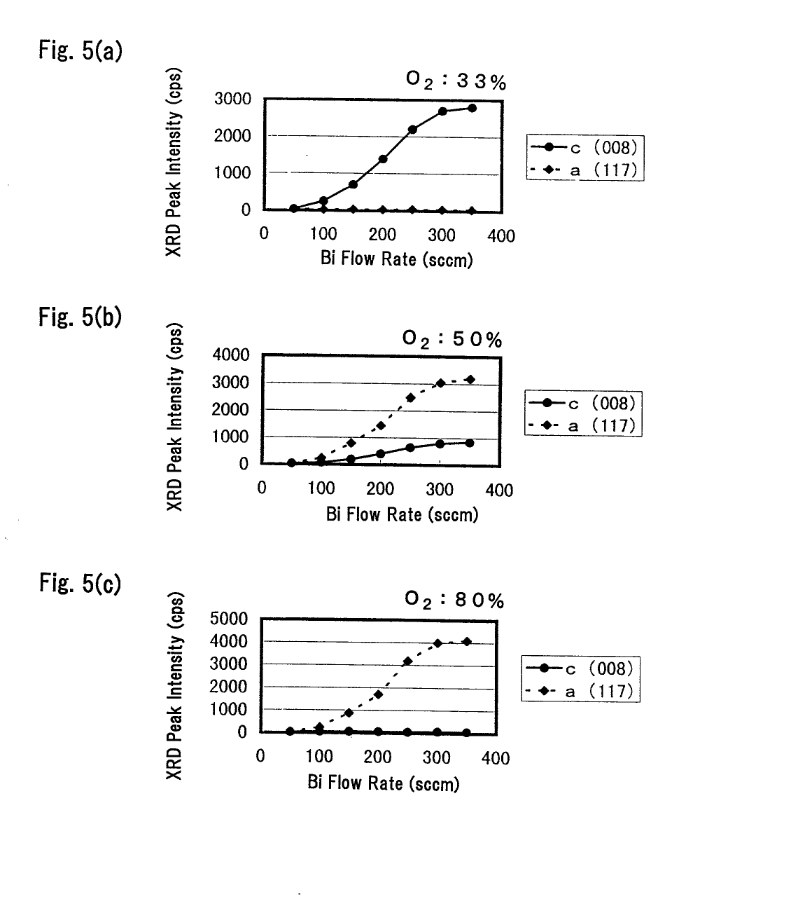

Next, FIGS. 5(a) to 5(c) each show a relationship between the Bi/Ti compositional ratio (flow rate of an Ar carrier gas containing a Bi material) and the XRD peak intensity for each oxygen concentration.

From FIGS. 5(a) to 5(c), it will be understood that the oxygen concentration determines the orientation direction of the Bi₄Ti₃O₁₂ thin film, and the magnitude of the orientation is determined by the Bi/Ti compositional ratio. In other words, it has been found out that the oxygen concentration determines a surface direction along which the Bi₄Ti₃O₁₂ ferroelectric thin film can easily grow, and the amount of the Bi₄Ti₃O₁₂ crystals arranged in the surface direction is determined by the Bi/Ti compositional ratio.

### EXAMPLE 2

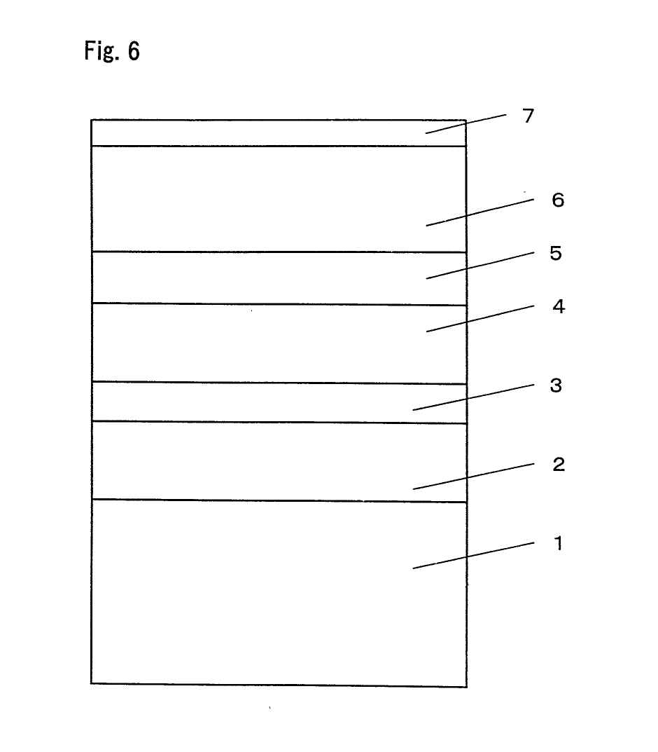

A Pt upper electrode 8 having a diameter of 100 μmφ and a thickness of 100 nm was formed by vapor deposition on a Bi₄Ti₃O₁₂ ferroelectric thin film formed in the above Example 1, thereby to fabricate a ferroelectric capacitor of FIG. 6, and its hysteresis properties were evaluated.

Here, in this evaluation, the thin films formed using 50 sccm of the Ar carrier gas containing the Bi material (Bi/Ti≈0.4) were excluded from the evaluation of the hysteresis properties because the thin films showed a paraelectric (ordinary dielectric) pyrochlore (Bi₂Ti₂O₇) phase irrespective of the orientation direction, as shown in FIG. 4. Also, with respect to the thin films formed using 350 sccm of the Ar carrier gas containing the Bi material (Bi/Ti≈1.5), the leakage current density was large and it was not possible to observe the hysteresis properties although the thin films showed a single Bi₄Ti₃O₁₂ ferroelectric phase, irrespective of the orientation direction, as shown in FIG. 4.

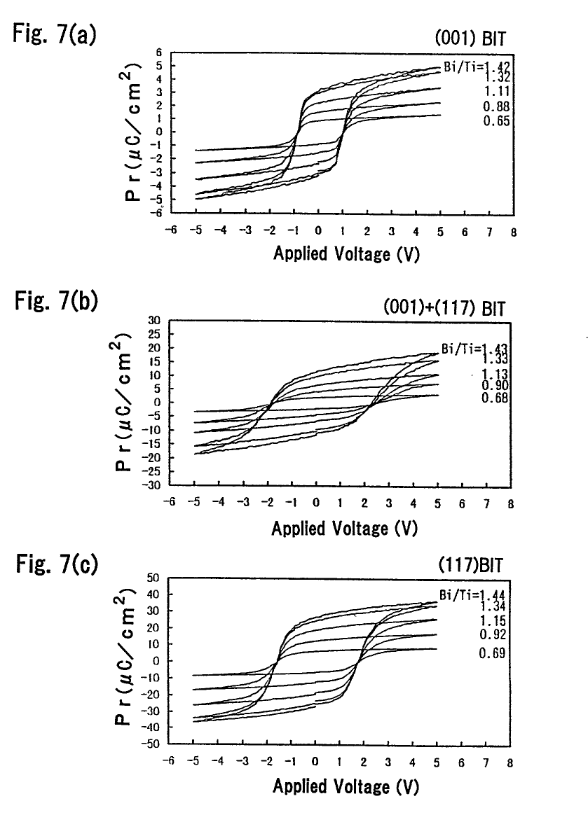

FIGS. 7(a) to 7(c) each show hysteresis properties for each oxygen concentration when an alternating current voltage having the maximum voltage of 5V is applied. In FIGS. 7(a) to 7(c), “(001) BIT”, “(001)+(117) BIT” and “(117) BIT” represent samples prepared with oxygen concentrations of 33%, 50% and 80%, respectively, and the same applies to the subsequent figures.

From FIGS. 7(a) to 7(c), it will be clearly understood that all the Bi₄Ti₃O₁₂ ferroelectric thin films formed using 100, 150, 200, 250 and 300 sccm of the flow rate of the Ar carrier gas containing the Bi material (0.65<Bi/TI<1.45) showed hysteresis properties.

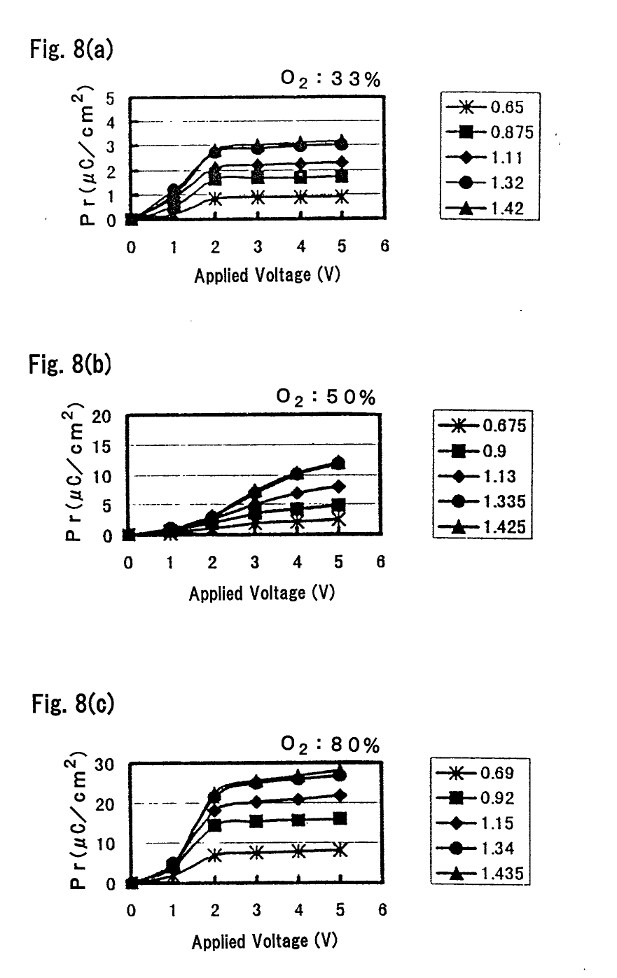

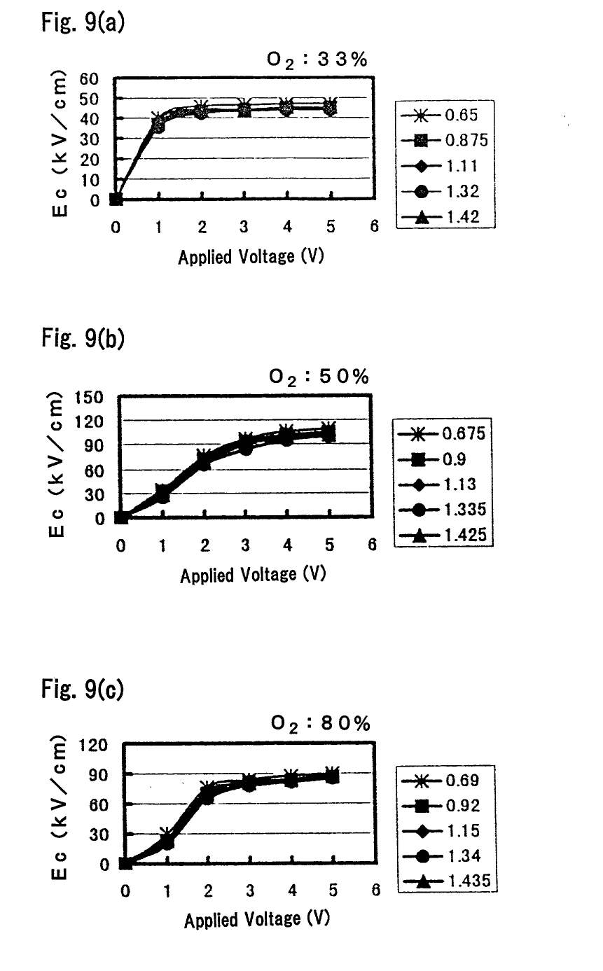

FIGS. 8(a) to 8(c) and FIGS. 9(a) to 9(c) show saturation properties by plotting values of the residual polarization Pr and the coercive field Ec for each oxygen concentration when an alternating current voltage having the maximum voltage of 1, 2, 3, 4 or 5 V was applied, using the Bi/Ti compositional ratio as a parameter. From FIGS. 8(a) to 8(c) and FIGS. 9(a) to 9(c), it will be clearly understood that the Bi₄Ti₃O₁₂ ferroelectric thin films each show a good saturation property. Especially, the c-axis orientation Bi₄Ti₃O₁₂ thin film prepared at an oxygen concentration of 33% ((001) BIT) showed a saturation both in the residual polarization Pr and the coercive field Ec even when an alternating current voltage having the maximum voltage of 2 V was applied.

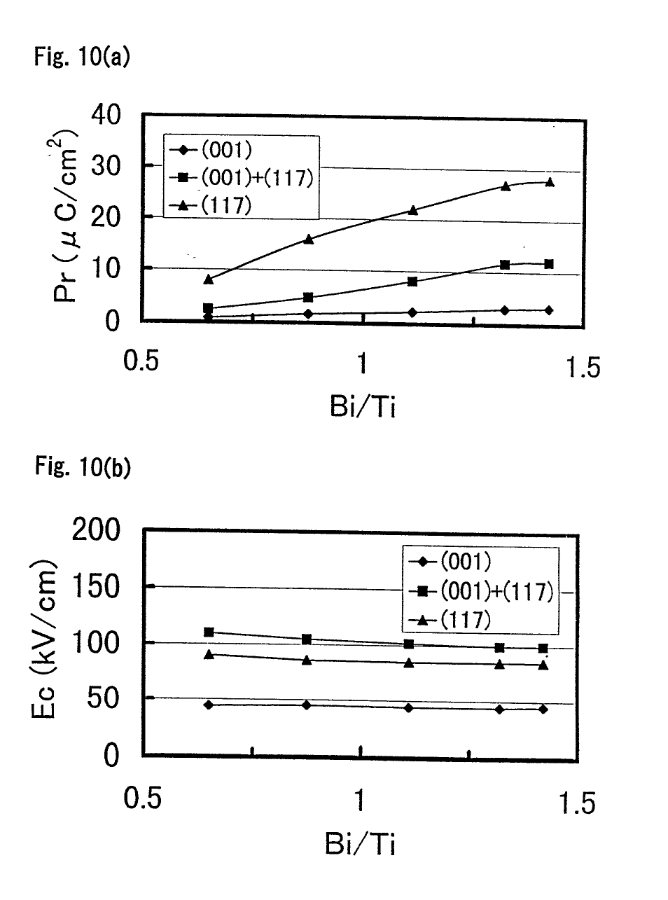

FIG. 10(a) shows a relationship between the Bi/Ti compositional ratio and the residual spontaneous polarization Pr when an alternating current voltage having the maximum voltage of 5V was applied, using the oxygen concentration (orientation direction) as a parameter. FIG. 10(b) shows a relationship between the Bi/Ti compositional ratio and the coercive field Ec when an alternating current voltage having the maximum voltage of 5V was applied, using the oxygen concentration (orientation direction) as a parameter.

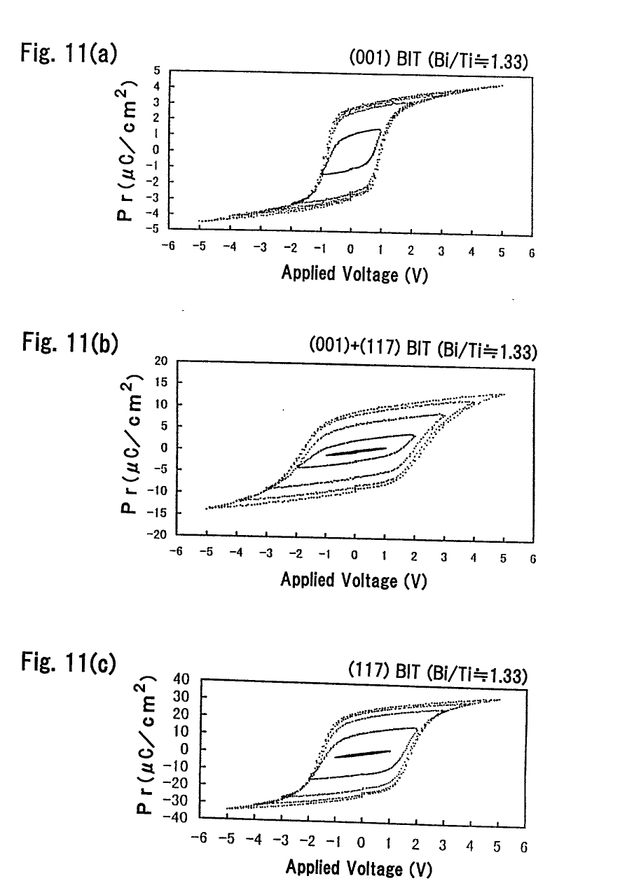

FIGS. 11(a) to 11(c) show, for each oxygen concentration (orientation direction), a superposition of hysteresis curves when alternating current voltages having the maximum voltage of 1, 2, 3, 4 and 5 V were each applied to a Bi₄Ti₃O₁₂ thin film having a stoichiometric composition (Bi/Ti=1.33) among these Bi₄Ti₃O₁₂ thin films.

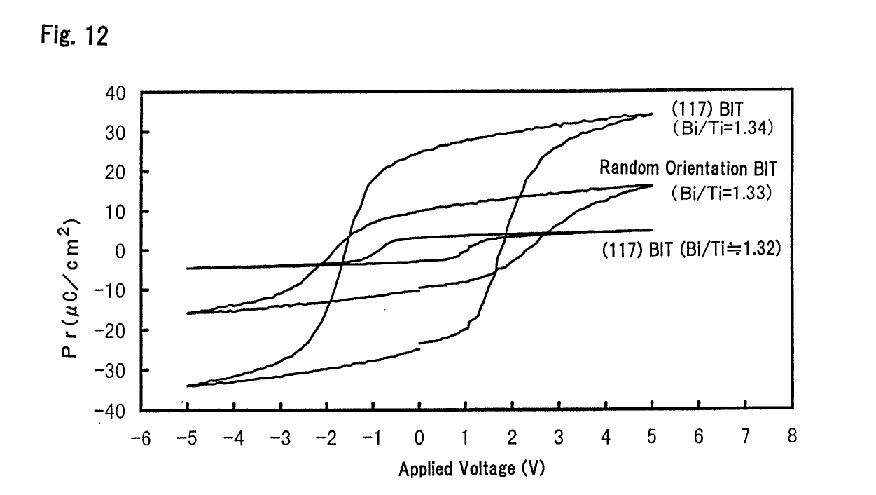

FIG. 12 shows a superposition of hysteresis curves for three oxygen concentrations (orientation directions) when an alternating current voltage having the maximum voltage of 5 V was applied.

From FIGS. 7(a) to 7(c), FIGS. 8(a) to 8(c), FIGS. 9(a) to 9(c) and especially FIGS. 10(a) and 10(c), it will be understood that, if the oxygen concentration is constant, the coercive field Ec is almost constant irrespective of the Bi/Ti compositional ratio, and only the residual spontaneous polarization Pr changes. The manner of change is similar to that of the XRD peak intensity of FIG. 5. In the case where Bi/Ti<1.33, the residual spontaneous polarization Pr increases in proportion to the change in the Bi/Ti compositional ratio; and in the case where Bi/Ti≧1.33, the residual spontaneous polarization Pr showed a tendency of saturation. In other words, although the coercive field Ec is the same, an arbitrary residual polarization value could be obtained, and moreover, in a sufficiently saturated state.

Further, the ferroelectric properties can be drawn out in accordance with the orientation direction of the Bi4Ti₃O₁₂ thin film by varying the oxygen concentration, even with the same stoichiometric composition, as shown in FIGS. 11(a) to 11(c) and FIG. 12.

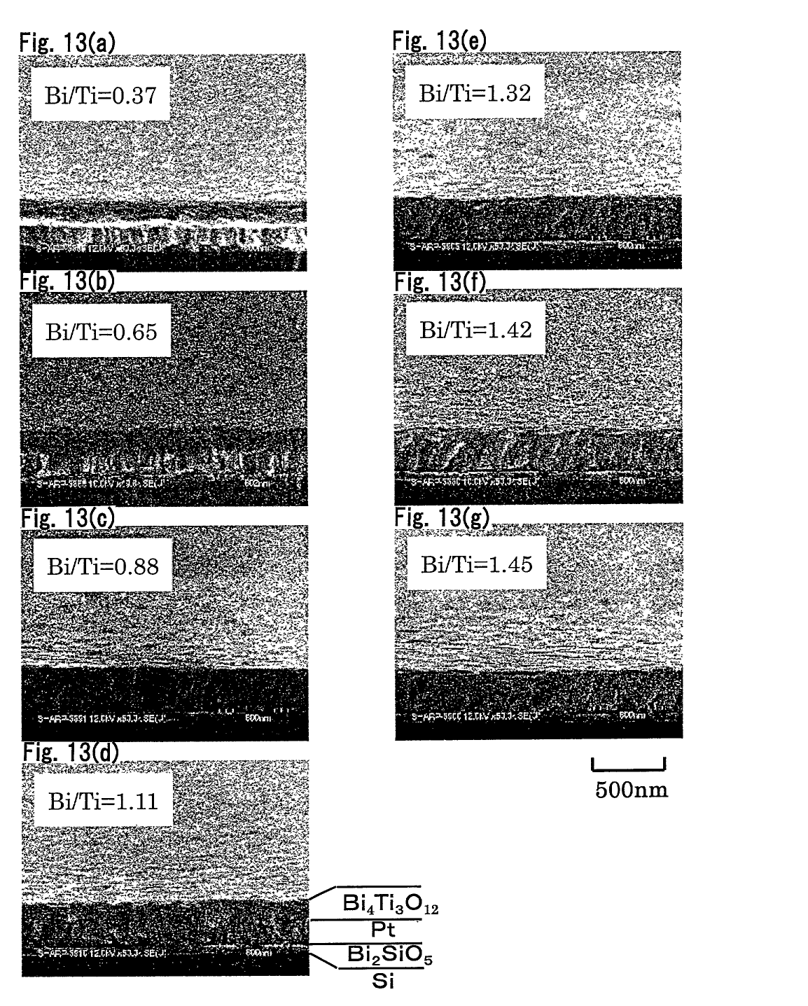

This can be explained by the fact that a pillar-shaped structure was confirmed in the Bi₄Ti₃O₁₂ thin film, as will be understood from a cross-sectional SEM image shown in FIG. 13.

Here, in this embodiment, since a ferroelectric thin film was directly formed on the Pt electrode without laminating a buffer layer such as TiO₂ layer, the low generation density of the BIT layer on the Pt electrode could be utilized, whereby the surface area was controlled to give the pillar-shaped structure ((001) orientation Bi₄Ti₃O₁₂, 02:33%).

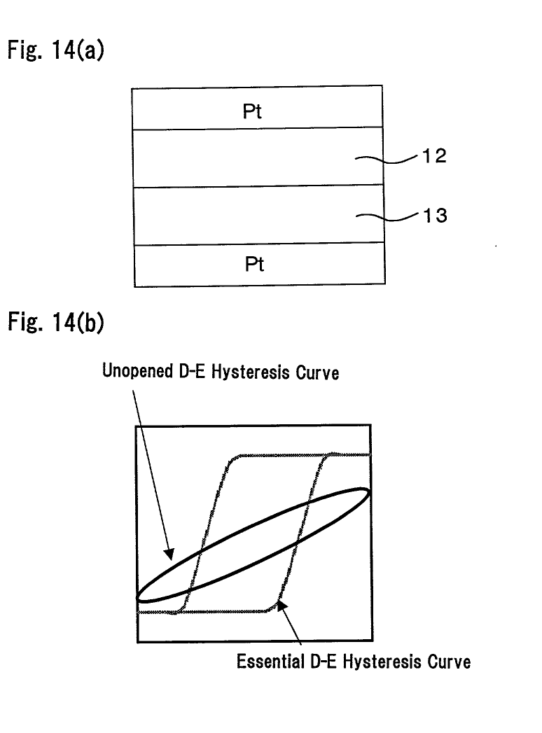

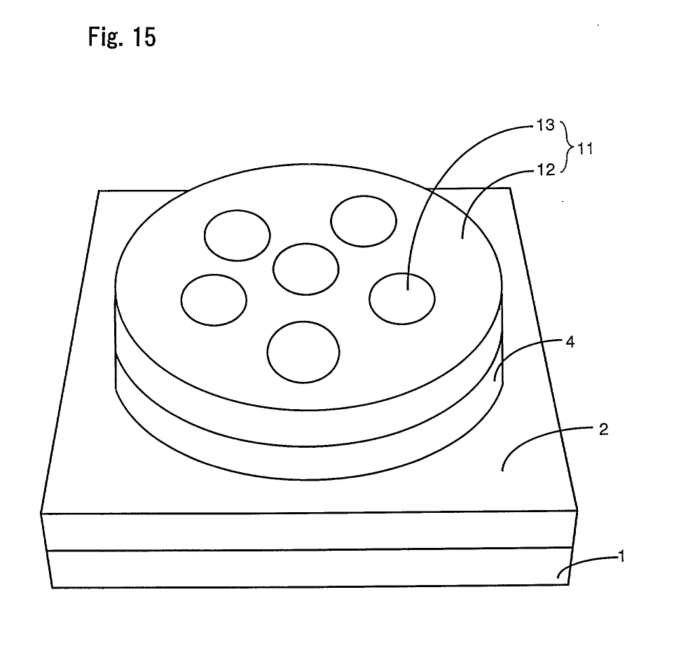

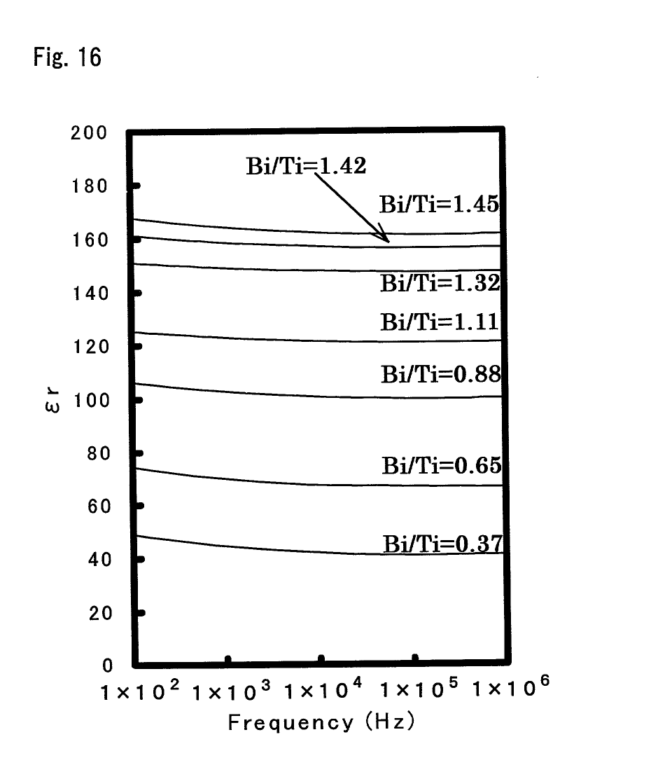

Referring to FIG. 14(a), if the ferroelectric thin film has a Bi/Ti composition shifted from the stoichiometric composition and has a structure in which an amorphous layer 12 and a BIT layer 13 are connected in series, it is inferred that the applied voltage would be applied to the amorphous layer and the hysteresis curve would open only a little, as shown in FIG. 14(b). However, referring to FIGS. 13 and 15, since the Bi₄Ti₃O₁₂ thin film 11 includes a pillar-shaped BIT layer 13 formed in the amorphous layer 12, the applied voltage is applied to the BIT layer 12 having a large relative dielectric constant, whereby a good hysteresis curve as shown in FIG. 7 was obtained. Also, referring to FIG. 16, the relative dielectric constant showed a change according as the ratio occupied by the BIT layer 12 in the amorphous layer 11 changed.

In other words, it is understood that the oxygen concentration determines the orientation (direction of the pillar of the BIT layer), and the Bi/Ti compositional ratio determines the area of the BIT layer.

The residual spontaneous polarization Pr and the coercive field Ec obtained in accordance with the present invention are Pr≈1 to 3 μC/cm² and Ec≈40 kV/cm for an oxygen concentration of 33%; Pr≈2 to 12 μC/cm and Ec≈100 kV/cm for an oxygen concentration of 50%; and Pr≈7 to 30 μC/cm and Ec≈85 kV/cm for an oxygen concentration of 80%.

It is known that, on the Pt, the BIT has a low density of nucleation (generation of nuclei) by nature and tends to grow in huge particles. The present invention utilizes the low density of nucleation of the BIT on the Pt to grow its nuclei in the direction of the thickness of the film and at the same time, control the size of BIT pillars by varying the Bi/Ti compositional ratio. Thereby, the proportion of area occupied by BIT pillars per given area can be controlled. As a result, a desired pillar structure is obtained in the BIT layer. This leads to the realization of a low relative dielectric constant that has not been achieved conventionally. It is also known that the BIT tends to orient in a c-axis on the Pt due to its anisotropy in growth rate. However, oxygen octahedrons in a BIT lattice exhibits a good matching with a Pt(111). This means that the BIT has a tendency to a (117) orientation. It is considered that the BIT has the (117) orientation where the concentration of oxygen is low and that it has the c-axis orientation where the concentration of oxygen is high.

These values are obtained not in correspondence with the oxygen concentrations of 33%, 50% and 80% in the film forming step, but it is effective at other oxygen concentrations such as 40% and 65%. In other words, this means that the Bi₄Ti₃O₁₂ thin film has a single c-axis orientation at an oxygen concentration of 33%; the c-axis component gradually decreases and simultaneously the (117) orientation component gradually increases if the oxygen concentration is higher than 33%; and the Bi₄Ti₃O₁₂ thin film has a single (117) orientation at an oxygen concentration of 80%.

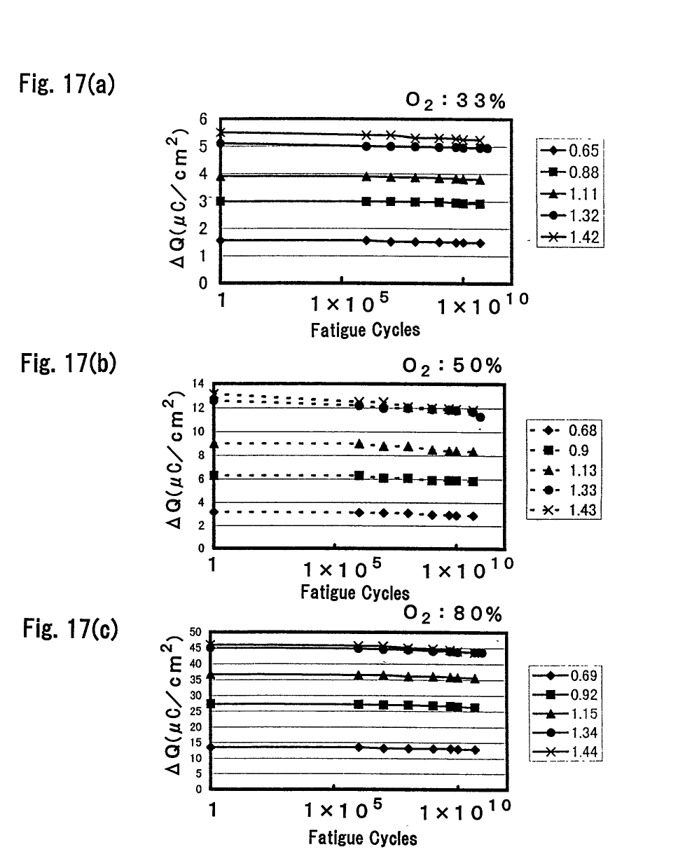

Further, the FIG. 17(a) to 17(c) show evaluation of fatigue properties of the Bi₄Ti₃O₁₂ thin film using an alternating current voltage having the maximum voltage of 3V. Each Bi₄Ti₃O₁₂ thin film was subjected to repetition of polarization inversion for 5×10¹⁰ times (1×10¹¹ times for a thin film having a stoichiometric composition). This showed an extremely favorable result that the ratio of decrease in the switching electric charge was at most less than 10% and in most cases less than 5%. This seems to be because the ferroelectric properties of each thin film at the applied voltage of 3V showed almost a saturation.

According to the method of manufacturing an oxide ferroelectric thin film of the present invention, an oxide ferroelectric thin film having an arbitrary residual spontaneous polarization Pr, an arbitrary coercive field Ec and/or an arbitrary relative dielectric constant Er can be manufactured by completely controlling the orientation (direction and magnitude) including the crystallinity by controlling the ratio of the oxygen gas flow rate relative to the total gas flow rate to control the orientation direction and by controlling the flow rate of at least one of the material gases of constituent elements of the ferroelectric thin film other than oxygen to control the compositional ratio of the constituent elements other than oxygen in manufacturing the oxide ferroelectric thin film on the substrate by the MOCVD method. Further, by clearly determining these controlling conditions, leakage currents generated in the oxide ferroelectric thin film and the deterioration in the durability against the polarization inversion can be suppressed, and also the voltage applied to the oxide ferroelectric thin film can be controlled.

Therefore, in accordance with the present invention, in realizing a device that utilizes a ferroelectric substance, it is possible to provide a ferroelectric thin film having ferroelectric properties that satisfy designed values required in the device, by arbitrarily controlling the residual polarization Pr, the coercive field Ec and/or the relative dielectric constant E r.

Although the present invention has fully been described by way of example with reference to the accompanying drawings, it is to be understood that various changes and modifications will be apparent to those skilled in the art. Therefore, unless otherwise such changes and modifications depart from the scope of the invention, they should be construed as being included therein.

What we claim is:

1. A method of manufacturing an oxide ferroelectric thin film of Bi, Ti and O by an MOCVD method on a substrate having an electrode formed thereon, comprising the step of supplying material gases capable of forming the oxide ferroelectric thin film onto the substrate, wherein
an oxygen gas flow rate relative to a total gas flow rate of the material gases is controlled to a value required for obtaining the oxide ferroelectric thin film having a predetermined orientation and/or coercive field, and
a flow rate of at least one of the material gases containing constituent elements other than oxygen constituting the oxide ferroelectric thin film is controlled so that a compositional ratio of the constituent elements other than oxygen constituting the oxide ferroelectric thin film is a value required for obtaining the oxide ferroelectric thin film having a predetermined residual polarization and/or relative dielectric constant.

2. A method of manufacturing an oxide ferroelectric thin film of Bi, Ti and O by an MOCVD method on a substrate having an electrode formed thereon, comprising the step of controlling a Bi/Ti compositional ratio by varying a flow rate of at least one of material gases containing constitutional elements other than oxygen constituting the oxide ferroelectric thin film, so as to control a density of crystal nucleation in the oxide ferroelectric thin film.

3. The method of claim 1 or 2, wherein the oxygen gas flow rate relative to the total gas flow rate of the material gases is within a range of 33 to 80 vol % and the flow rate of at least one of the material gases containing Bi or Ti is controlled so that a Bi/Ti compositional ratio is within a range of 0.4 to 1.5.

4. An oxide ferroelectric thin film formed directly on an electrode formed on a substrate, wherein the oxide ferroelectric thin film has a pillar-formed structure.

5. An oxide ferroelectric thin film formed directly on an electrode formed on a substrate, wherein orientation of the oxide ferroelectric thin film is one of a c-axis dominant orientation, a random orientation in which a c-axis orientation and a (117) orientation are mainly dominant, and a (117) dominant orientation, and a Bi/Ti compositional ratio is within a range of 0.4 to 1.5.

6. An oxide ferroelectric thin film element comprising:
a substrate;
a first electrode formed on the substrate;
an oxide ferroelectric thin film formed directly on the first electrode by a method as set forth in claim 1 or 2; and
a second electrode formed on the oxide ferroelectric thin film.

7. An oxide ferroelectric thin film element comprising:
a substrate;
a first electrode formed on the substrate;
an oxide ferroelectric thin film as set forth in claim 4 or 5 formed directly on the first electrode; and
a second electrode formed on the oxide ferroelectric thin film.

8. The oxide ferroelectric thin film element of claim 7,
wherein the oxide ferroelectric thin film connects to the first and second electrodes in series by the pillar-formed structure.
